(19) United States
(12) Patent Application Publication
(10) Pub. No.: US 2004/0100247 A1
(43) Pub. Date: May 27, 2004

(54) System for compensating a voltage of a negative-phase-sequence component in a power system

(75) Inventors: Tadashi Matsumoto, Osaka (JP); Seiji Tange, Tokyo (JP); Toshio Nomura, Hyogo (JP)

Correspondence Address: LEYDIG VOIT & MAYER, LTD, 700 THIRTEENTH ST. NW, SUITE 300, WASHINGTON, DC, 20005-3960, US

(73) Assignee: TMT&D Corporation, Tokyo (JP)

(21) Appl. No.: 10/704,805

(22) Filed: Nov. 12, 2003

(30) Foreign Application Priority Data
Nov. 25, 2002 (JP) 2002-340836

(51) Int. Cl. G01R 25/00

(52) U.S. Cl. 324/86; 323/205

(57) ABSTRACT

The system of the present invention includes transformers 12-1, 12-2 and 12-3 for detecting voltages received at a power receiving point in the power system, a negative-phase-sequence component voltage detector 18 for arithmetically operating the voltage of a negative-phase sequence component from the received voltages and amplifying the voltage of a negative-phase-sequence component to output the amplified voltage of a negative-phase-sequence component, and a negative-phase-sequence voltage compensation input unit 14 for injecting the outputted voltage of a negative-phase-sequence component into a system as an object of compensation to compensate for the received voltages at the power receiving point. The voltage of a negative-phase-sequence component is cancelled for a load 17 as an object.

### BACKGROUND OF THE INVENTION

1. Field of the Invention

The present invention relates in general to a system for compensating a voltage (or a current) of a negative-phase-sequence component in a power system. In particular, the invention relates to a system for compensating a voltage of a negative-phase-sequence component in voltages received by a power user.

2. Related Background Art

In general, as for conventionally-known loads in a power system at a power receiving point of a power user (hereinafter referred to as a load in a power user), there are a single-phase load such as electric light illumination, a three-phase electric power load such as an induction motor, and the like, and those loads are supplied with electric powers from a three-phase power supply. Three-phase voltages are balanced in an original power supply. However, it is not too much to say that in general, the balance is lost at the power receiving point of the power user due to the whole load quantities of three-phases. That is to say, the unbalance of the loads in other power users, the unbalanced state of all loads connected to transmission lines or distribution lines, the unbalance of the loads in the power user concerned, and the like cause unbalance of the three-phase voltages at the power receiving point of the power user through line impedances of the transmission lines. As a result, the balance of three-phase voltages is lost (For, example, see “A Penetrating Gaze at One Open Phase: Analyzing the Polyphase Induction Motor Dilemma”, M. Shan Griffith, November/December 1977, IEEE Transactions on Industry Applications, Vol. 1A-13, No. 6).

Conventionally, protection for a power receiving point of a power user is carried out using a protective relay, an insufficient voltage/overvoltage relay, or the like. However, the protection for three-phase unbalanced voltages is not positively carried out.

But, while in the conventional equipment, in a place where induction motors are installed, a negative-phase-sequence component overcurrent relay is applied to the individual induction motors, the compensation for a voltage (or a current) of a negative-phase-sequence component is not yet carried out.

In the conventional power receiving form as described above, there is encountered a problem in that unbalance of three-phase voltages at a power receiving point exerts a bad influence on equipment installed in a place of a power user, in particular, a three-phase induction motor.

Due to the bad influence produced by the unbalance in three-phases, there is encountered a problem in that in addition to a normal three-phase induction motor, even a three-phase induction motor which does not get to burning consumes an unnecessary electric power to cause a power user to pay an excessive electricity charge, and also this unbalanced currents increase the unbalanced voltages of a power distribution system or a power transmission system to exert a bad influence on other power users as well.

Also, there is encountered a problem in that the unbalanced currents increase a watt loss in a distribution line or a transmission line, causing a loss in a power distribution process to consume an unnecessary energy on a power supplier side.

### SUMMARY OF THE INVENTION

The present invention has been made in order to solve the above-mentioned problems, and therefore has an object to obtain a system for compensating a voltage of a negative-phase-sequence component in a power system which is capable of supplying balanced three-phase voltages to a load in a power user to enable safety running thereof by installing a compensator for compensating a voltage of a negative-phase-sequence component.

According to the present invention, there is provided a system for compensating a voltage of a negative-phase-sequence component in a power system, including: received voltage detecting means for detecting received voltages at a power receiving point in a power system which is connected to load equipment and negative-phase-sequence component voltage arithmetically operating means for arithmetically operating the voltage of a negative-phase-sequence component from the received voltages thus detected. The system also includes negative-phase-sequence component voltage compensation inputting means for injecting a voltage based on the voltage of a negative-phase-sequence component into a system as an object of compensation to compensate for the received voltages at the power receiving point, in which the voltage of a negative-phase-sequence component is cancelled to supply a power to the load equipment. Then, the compensator for compensating a voltage of a negative-phase-sequence component is thus installed, whereby the balanced three-phase voltage can be supplied to a load in a power user to enable safety running thereof.

### BRIEF DESCRIPTION OF THE DRAWINGS

In the accompanying drawings:

FIG. 1 is a circuit diagram, partly in block diagram, showing a configuration of a system for compensating a voltage of a negative-phase-sequence component in a power system according to Embodiment 1 of the present invention;

FIG. 2 is a circuit diagram, partly in block diagram, showing a configuration of a detector for detecting a voltage of a negative-phase-sequence component according to Embodiment 1 of the present invention;

FIG. 3 is a circuit diagram showing a configuration of an input unit for compensation for a voltage of a negative-phase-sequence component of the present invention;

FIG. 4 is a diagram showing typical formulas in the method of symmetrical coordinates concerned with the present invention;

FIGS. 5A and 5B are respectively vector diagrams useful in explaining a vector of a voltage (current) of a negative-phase-sequence component;

FIGS. 6A, 6B, and 6C are respectively a circuit diagram and vector diagrams useful in explaining an example of deriving a voltage of a negative-phase-sequence component from three-phase voltages;

FIGS. 7A, 7B, and 7C are respectively a circuit diagram and vector diagrams useful in explaining an example of deriving a current of a negative-phase-sequence component in the form of a voltage from three-phase currents;

FIG. 8 is a circuit diagram, partly in block diagram, showing a configuration of a system for compensating a voltage of a negative-phase-sequence component in a power system according to Embodiment 2 of the present invention;

FIG. 9 is a circuit diagram, partly in block diagram, showing a configuration of a detector for detecting a voltage of a negative-phase-sequence component according to Embodiment 2 of the present invention;

FIG. 10 is a circuit diagram, partly in block diagram, showing a configuration of a system for compensating a voltage of a negative-phase-sequence component in a power system according to Embodiment 3 of the present invention;

FIG. 11 is a circuit diagram, partly in block diagram, showing a configuration of a detector for detecting a voltage of a negative-phase-sequence component according to Embodiment 3 of the present invention;

FIG. 12 is a circuit diagram, partly in block diagram, showing a configuration of a system for compensating a voltage of a negative-phase-sequence component in a power system according to Embodiment 4 of the present invention;

FIG. 13 is a circuit diagram, partly in block diagram, showing a configuration of a detector for detecting a voltage of a negative-phase-sequence component according to Embodiment 4 of the present invention;

FIG. 14 is a circuit diagram, partly in block diagram, showing a configuration of a system for compensating a voltage of a negative-phase-sequence component in a power system according to Embodiment 5 of the present invention;

FIG. 15 is a circuit diagram, partly in block diagram, showing a configuration of a detector for detecting a voltage of a negative-phase-sequence component according to Embodiment 5 of the present invention;

FIG. 16 is a circuit diagram, partly in block diagram, showing a configuration of a system for compensating a voltage of a negative-phase-sequence component in a power system according to Embodiment 6 of the present invention;

FIG. 17 is a circuit diagram, partly in block diagram, showing a configuration of a detector for detecting a voltage of a negative-phase-sequence component according to Embodiment 6 of the present invention; and

FIG. 18 is a diagram useful in explaining an influence exerted on an input current due to a voltage of a negative-phase-sequence component in a three-phase induction motor.

### DESCRIPTION OF THE PREFERRED EMBODIMENTS

### Embodiment 1

A system for compensating a voltage of a negative-phase-sequence component in a power system according to the present invention is designed in order to make it possible that in a point in which it is necessary to compensate three-phase unbalanced voltages in a power system of a power user or the like (e.g., an power receiving point of the power user, a point in which a three-phase induction motor is installed, or the like), a voltage of a negative-phase-sequence component contained in a line voltage is detected from voltages or currents, and the compensation is forcibly carried out for that point with a voltage of a negative-phase-sequence component to cancel the voltage of a negative-phase-sequence component to allow three-phase balanced voltages to be supplied to a load.

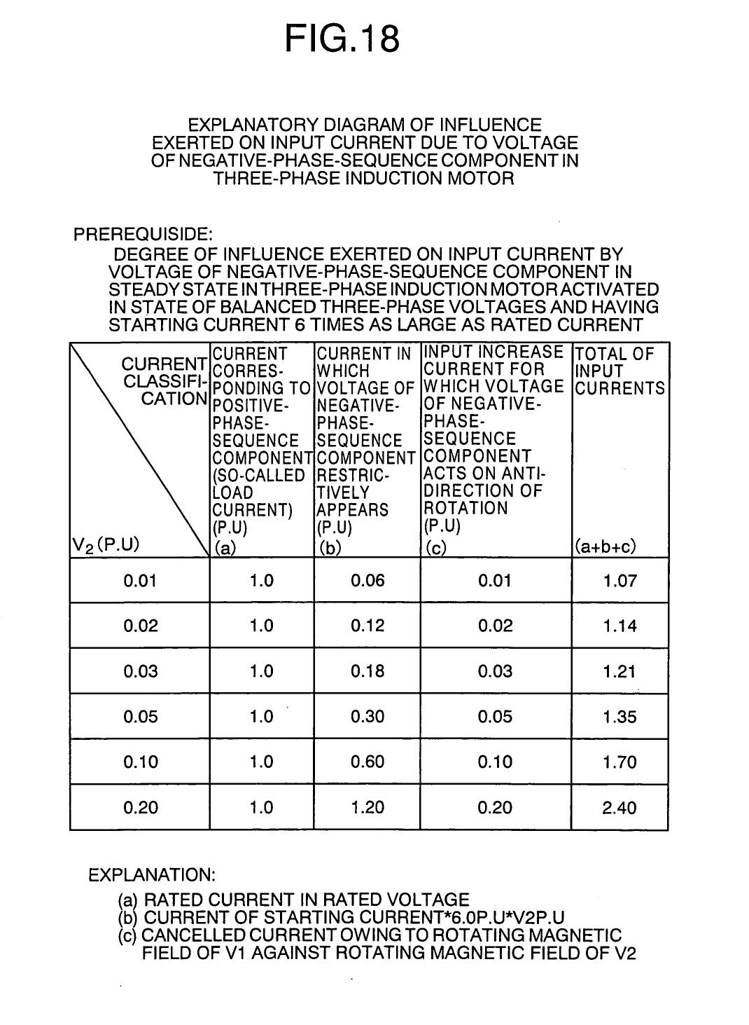

Incidentally, for reference, a bad influence exerted on an input current due to a voltage of a negative-phase-sequence component in a conventional apparatus is shown in FIG. 18. FIG. 18 is a diagram showing the degree of an increase in input current with respect to a rate of a voltage of a negative-phase-sequence component contained in supplied voltages in case of a three-phase induction motor having a locked rotor current 6 times as large as a rated current. As can be understood from FIG. 18 as well, even in case of a voltage V₂ of a negative-phase-sequence component of 1% (V₂: 0.01), an input current may be increased by as much as 7% (the total of input currents: 1.07). If the voltage V₂ of a negative-phase-sequence component is equal to or smaller than 2% or so at the most (V₂: equal to or smaller than 0.02), then the induction motor barely induce that voltage V₂ (the total of input currents: equal to or smaller than 1.14). If the voltage V₂ of a negative-phase-sequence component is contained by as much as 5% (V₂: 0.05), then the input current is increased by as much as 35% (the total of input currents: 1.35), and as a result, the induction motor will be burnt down before long. From this fact, it is clear that a negative-phase-sequence component has such a harmful effect. In the light of the foregoing, preferred embodiments of the present invention will hereinafter be described in detail with reference to the accompanying drawings.

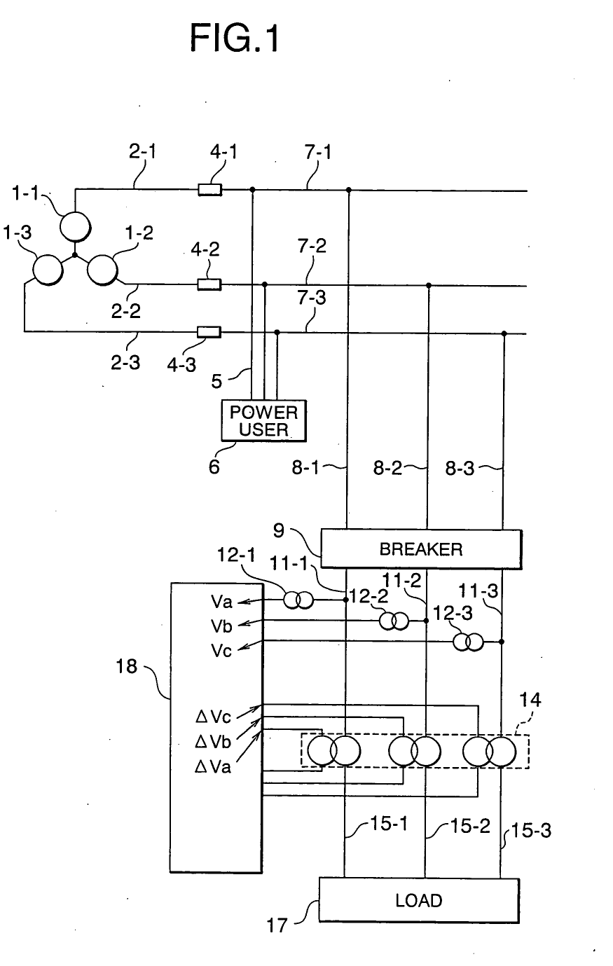

FIG. 1 is a circuit diagram, partly in block diagram, showing a configuration of a system for compensating a voltage of a negative-phase-sequence component in a power system according to Embodiment 1 of the present invention. In FIG. 1, transmission lines (or distribution lines) 2-1, 2-2 and 2-3 are connected to three-phase power supplies 1-1, 1-2 and 1-3, respectively. Line impedances 4-1, 4-2 and 4-3 are provided in the transmission lines 2-1, 2-2 and 2-3, respectively. A load of a power user 6 is connected to the transmission lines 2-1, 2-2 and 2-3 through three-phase leading lines 5. Incidentally, reference numerals 7-1, 7-2 and 7-3 respectively designate transmission lines or distribution lines over which the electric powers are supplied to other loads.

In addition, reference numerals 8-1, 8-2 and 8-3 respectively designate load leading lines, and a breaker 9 for protecting the power reception is provided at a power receiving point. Reference numerals 11-1, 11-2 and 11-3 respectively designate connection lines distributed from the power receiving point to an input unit 14 for compensation of a voltage of a negative-phase-sequence component which will be described later. Also, reference numerals 15-1, 15-2 and 15-3 respectively designate connection lines distributed from the unit 14 for compensation of a voltage of a negative-phase-sequence component to a load 17.

In FIG. 1, reference numerals 12-1, 12-2 and 12-3 respectively designate transformers (PTs) for detecting received voltages received at the power receiving point. Reference numeral 18 designates a detector for detecting a voltage of a negative-phase-sequence component which serves to detect a voltage of a negative-phase-sequence component and to amplify the detected voltage of a negative-phase-sequence component up to a value required for the compensation. Also, reference numeral 14 designates the input unit for compensation of a voltage of a negative-phase-sequence component which serves to inject the voltage of a negative-phase-sequence component outputted from the detector 18 for detecting a voltage of a negative-phase-sequence component into a system as an object of the compensation to forcibly carry out the compensation for the power receiving point in order to cancel the voltage of a negative-phase-sequence component.

In FIG. 1, three-phase voltages Va, Vb and Vc as voltages received at the load point, which are induced from the transformers 12-1, 12-2 and 12-3, respectively, are induced into the detector 18 for detecting a voltage of a negative-phase-sequence component to be amplified up to the voltage (magnitude and phase) of a negative-phase-sequence component required for the compensation. Then, the resultant voltage is induced into the input unit 14 for compensation of a voltage of a negative-phase-sequence component to compensate system voltages as an object.

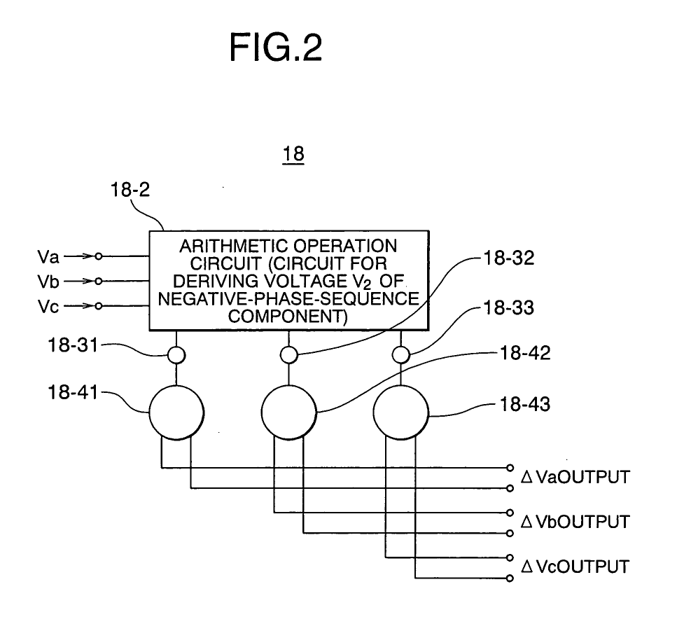

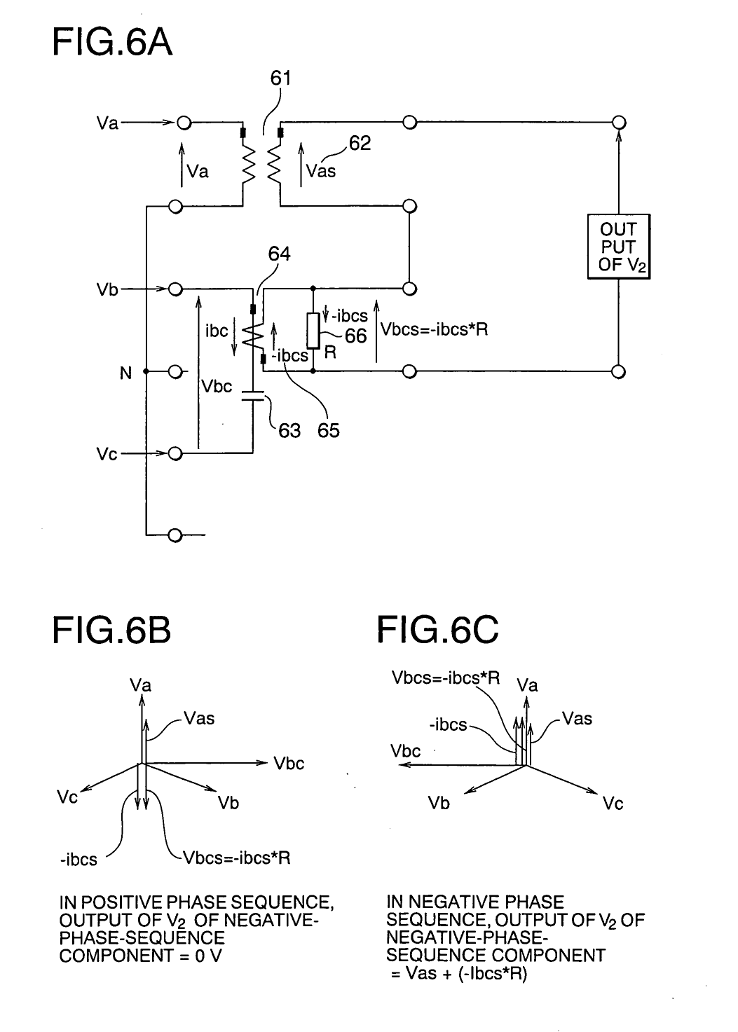

The detector 18 for detecting a voltage of a negative-phase-sequence component has a configuration shown in FIG. 2. In FIG. 2, reference numeral 18-2 designates an arithmetic circuit constituting a circuit for deriving a voltage V₂ of a negative-phase-sequence component from the three-phase voltages Va, Vb and Vc. Incidentally, a deriving method will be described later with reference to FIG. 6. Reference numerals 18-31, 18-32 and 18-33 respectively designate commanders for commanding a quantity and a phase of a compensation voltage for the detected voltage V₂ of a negative-phase-sequence component. Reference numerals 18-41, 18-42 and 18-43 respectively designate amplifiers for, on the basis of commands issued from the commanders 18-31, 18-32 and 18-33, amplifying the voltage V₂ of a negative-phase-sequence component up to a value required for the compensation to output the amplified voltage to allow the voltage V₂ of a negative-phase-sequence component to be injected to systems as an object of the compensation. Note that, the voltages obtained by amplifying the voltage of a negative-phase-sequence component are outputted in the form of ΔVa, ΔVb and ΔVc from the amplifiers 18-41, 18-42 and 18-43, respectively.

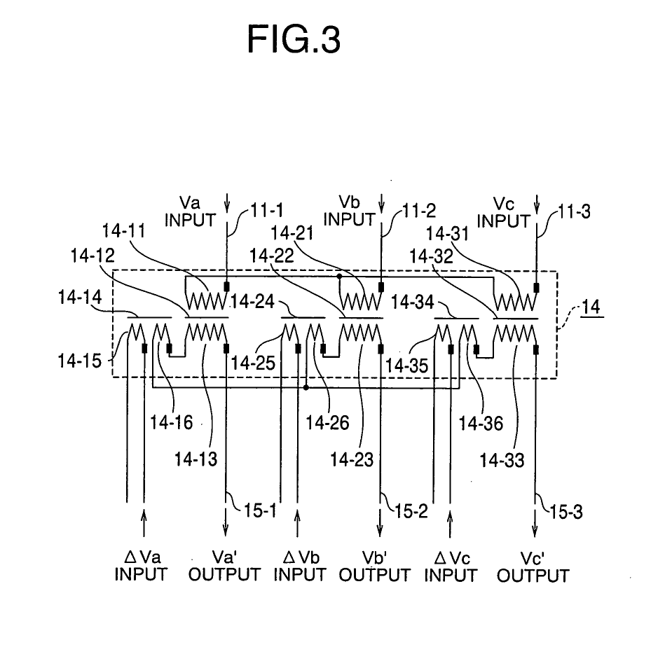

FIG. 3 is a circuit diagram showing an internal configuration of the input unit 14 for compensation of a voltage of a negative-phase-sequence component (Incidentally, in the following embodiments as well, this configuration will be adopted). The input unit 14 for compensation of a voltage of a negative-phase-sequence component receives as its inputs ΔVa, ΔVb and ΔVc obtained by amplifying the voltage V₂ of a negative-phase-sequence component outputted from the detector 18 for detecting a voltage of a negative-phase-sequence component. Using these inputs, the system voltages of systems 15-1, 15-2 and 15-3 as an object of the compensation are compensated to thereby cancel the voltage of a negative-phase-sequence component for the load 17. Incidentally, in FIG. 3, reference numerals 14-11, 14-21 and 14-31 respectively designate system primary wirings, reference numerals 14-12, 14-22 and 14-32 designate iron cores of the system primary wirings 14-11, 14-21 and 14-31, respectively, and reference numerals 14-13, 14-23 and 14-33 respectively designate system secondary wirings. Also, reference numerals 14-15, 14-25 and 14-35 respectively designate compensation primary wirings, reference numerals 14-14, 14-24 and 14-34 designate iron cores of the compensation primary wirings 14-15, 14-25 and 14-35, respectively, and reference numerals 14-16, 14-26 and 14-36 respectively designate compensation secondary wirings.

In FIG. 3, the iron cores 14-12 and 14-14 are not magnetically coupled to each other in terms of a structure. Similarly, the iron cores 14-22 and 14-24, and the iron cores 14-32 and 14-34 are not magnetically coupled to each other in terms of a structure.

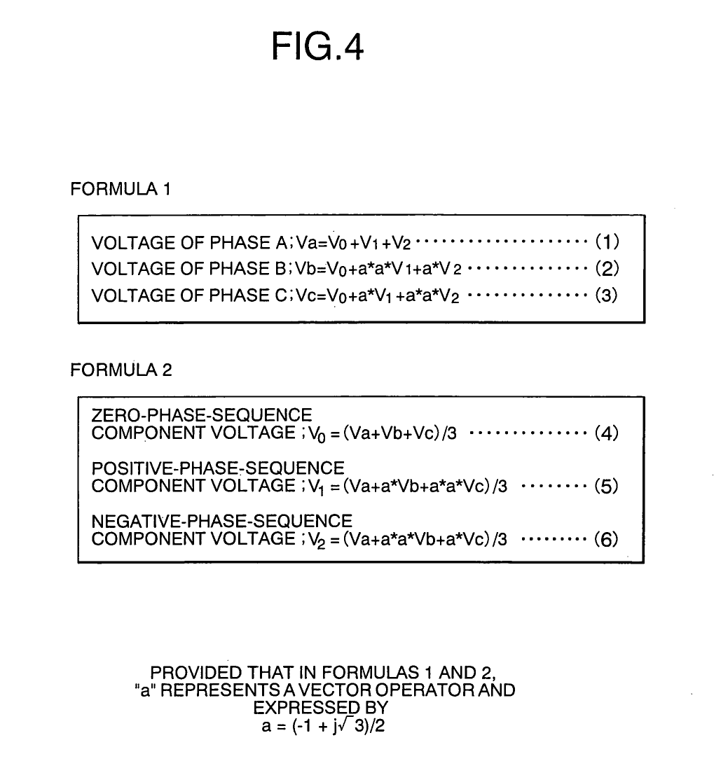

FIG. 4 is a diagram showing typical formulas according to the method of symmetrical coordinates. The voltages of three phases are expressed in the form of a formula 1. The formula 2 explains that a voltage of a zero-phase-sequence component, a voltage of a positive-phase-sequence component, and a voltage of a negative-phase-sequence component can be derived from voltages of the three phases.

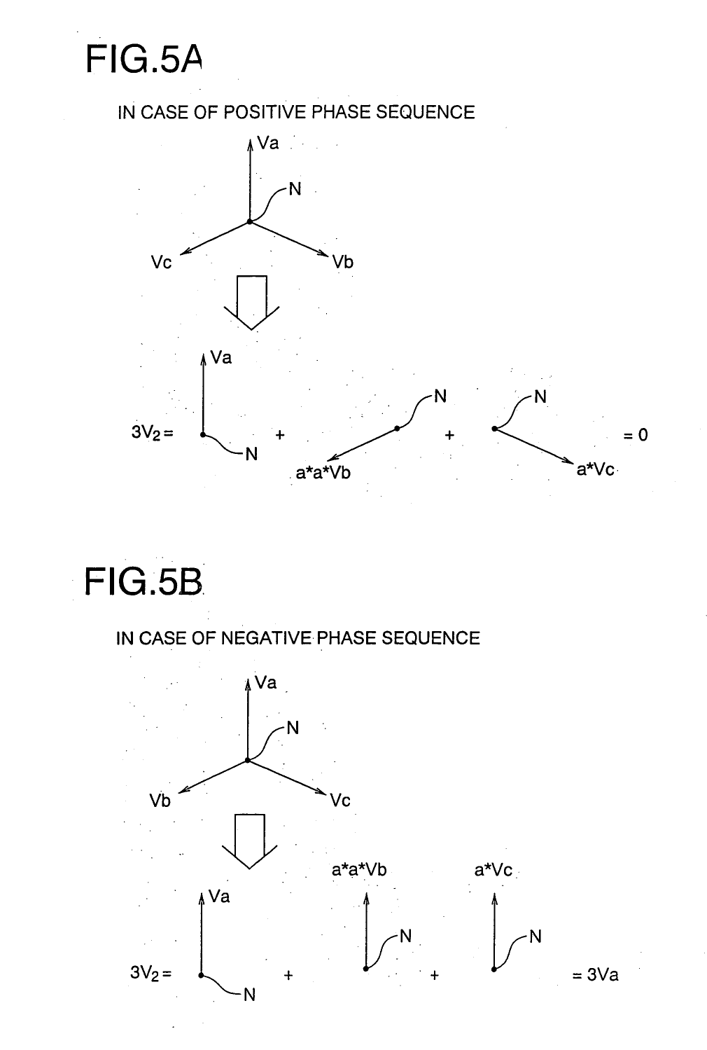

FIGS. 5A and 5B show a case where a voltage of a negative-phase-sequence component in Expression 6 of FIG. 4 is expressed in the form of vector. Incidentally, FIG. 5A shows a case of a positive phase sequence, while FIG. 5B shows a case of a negative phase sequence. That is to say, it is shown that when no voltage of a negative-phase-sequence component is contained in the system voltages Va, Vb and Vc, a relationship of V₂=0 is established. On the other hand, FIG. 5B represents that when the phase sequence is reversed as the most extreme example of the negative-phase-sequence component, the system voltage Va directly becomes the voltage V₂ of a negative-phase-sequence component.

As a method of detecting a voltage of a negative-phase-sequence component, detection can be realized by applying the contents of FIG. 4 and FIGS. 5A and 5B as they are. However, in this case, two vector manipulations are required for two phases (phases B and C), and therefore this becomes expensive in terms of a configuration of the system. For this reason, in the present invention, there is adopted a method of handling the phases B and C as one phase.

Although this method is limited to a power system in which a zero-phase-sequence component is ignorable, the adoption of this method may cause no problem since the high voltage system in Japan is the isolated neutral system.

FIG. 6A shows a method of detecting a voltage of a negative-phase-sequence component according to three-phase system voltages. In FIG. 6A, in a phase A, a voltage Vas 62 is generated on the secondary side of an auxiliary transformer 61 (Aux. PT). A capacitor (C) 63 is connected between a terminal corresponding to a phase B and a terminal corresponding to a phase C, a current caused to flow through the capacitor 63 is extracted on the primary side of an auxiliary current transformer (Aux. CT) 64, and a current −ibcs 65 is derived on the secondary side of the auxiliary current transformer 64 of a subtractive polarity to develop a voltage Vbcs=−ibcs*R across a resistor R 66.

The vector sum of Vas and Vbcs is figured out to obtain the voltage V₂ of a negative-phase-sequence component through the composition. Of course, a scalar quantity of Vas and that of Vbcs are designed to be equal. As shown in FIG. 6B, in case of a positive phase sequence, a relationship of V₂=0 is established. On the other hand, as shown in FIG. 6C, in case of a negative phase sequence, a relationship of V₂=2Va is established.

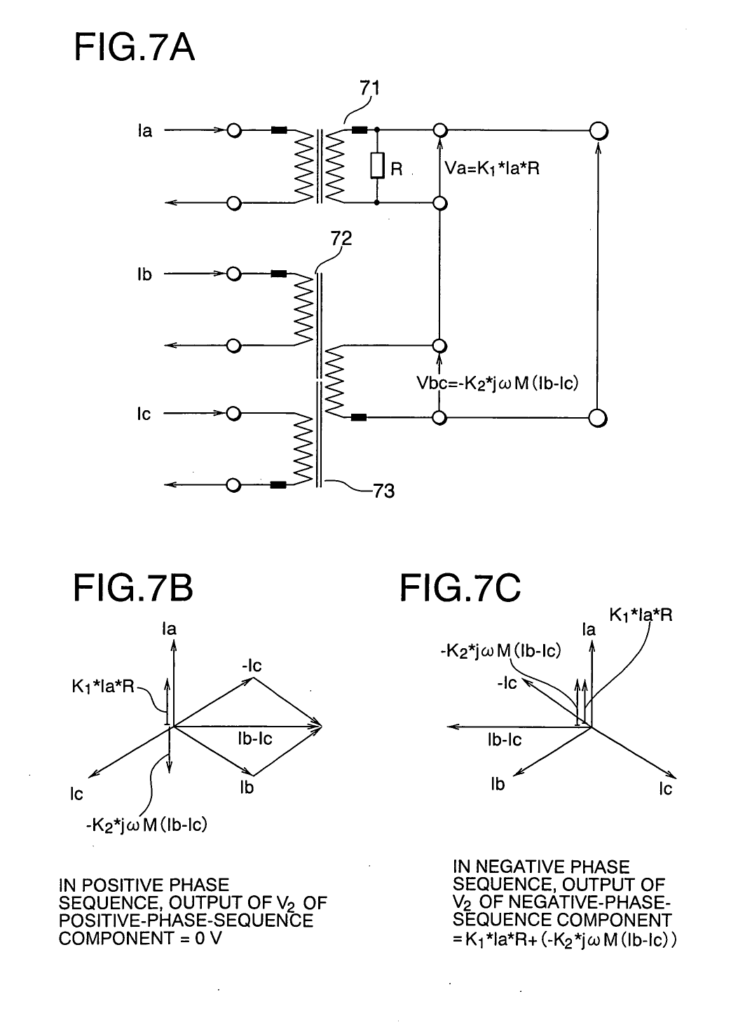

FIGS. 7A, 7B and 7C explain a method of detecting a voltage of a negative-phase-sequence component from line currents. In FIG. 7A, an auxiliary current transformer (Aux. CT) 71 is provided for the phase A, and auxiliary current transformers with a gap (Aux. GapCTs) 72 and 73 in which the primary side is of a two-windings type are provided for the phase B and the phase C, respectively, and also a polarity of the secondary side is made a subtractive polarity with the phase B as a reference so that a voltage of −jωM (Ib−Ic) is developed across the secondary side with an input of (Ib−Ic) as shown in the figure.

With such a configuration, as shown in FIG. 7B, in case of a positive phase sequence, a relationship of V₂=0 is established, while as shown in FIG. 7C, in case of a negative phase sequence, a relationship of V₂=2Va is established.

As described above, in this embodiment, the three-phase electric power system is provided with the deriving circuit 18-2 for deriving the voltage V₂ of a negative-phase-sequence component from the voltages Va, Vb and Vc received at a load point. Then the detected voltage V₂ of a negative-phase-sequence component is amplified by the amplifiers 18-41, 18-42 and 18-43, and the compensation is forcibly carried out for the load point by the input unit 14 for compensation of a voltage of a negative-phase-sequence component to cancel the voltage of a negative-phase-sequence component for the load 17. Hence, the balanced three-phase voltages can be supplied to a load of a power user, in particular, in case where the power user possesses a three-phase rotating apparatus such as a three-phase induction motor, or a three-phase synchronous motor. Thus, the three-phase rotating apparatus is prevented from falling into an over-load state to make the safety running thereof possible.

The compensation for the voltage of a negative-phase-sequence component lengthens a life span of equipment as an object. As a result, it becomes possible for a power user to extend the time of replacement of equipment, which leads to an effective resource application.

In addition to the three-phase rotating apparatus, even in a three-phase rectifier for example, magnitudes and phases of voltages of three phases are properly balanced. Hence, a ripple of a specific phase is prevented from being generated and hence it becomes possible to obtain a stable direct current.

Moreover, owing to the cancelled imbalance, a current which is excessively generated from the voltage of a negative-phase-sequence component is cancelled even for an upper power supply system. Thus, there is an effect that power transmission losses of lines can be reduced.

Also, owing to the cancelled imbalance, the spreading and magnifying of unbalanced voltages can be prevented even for other power users. Hence, it becomes possible to provide a stable environment for three-phase apparatuses of other power users.

### Embodiment 2

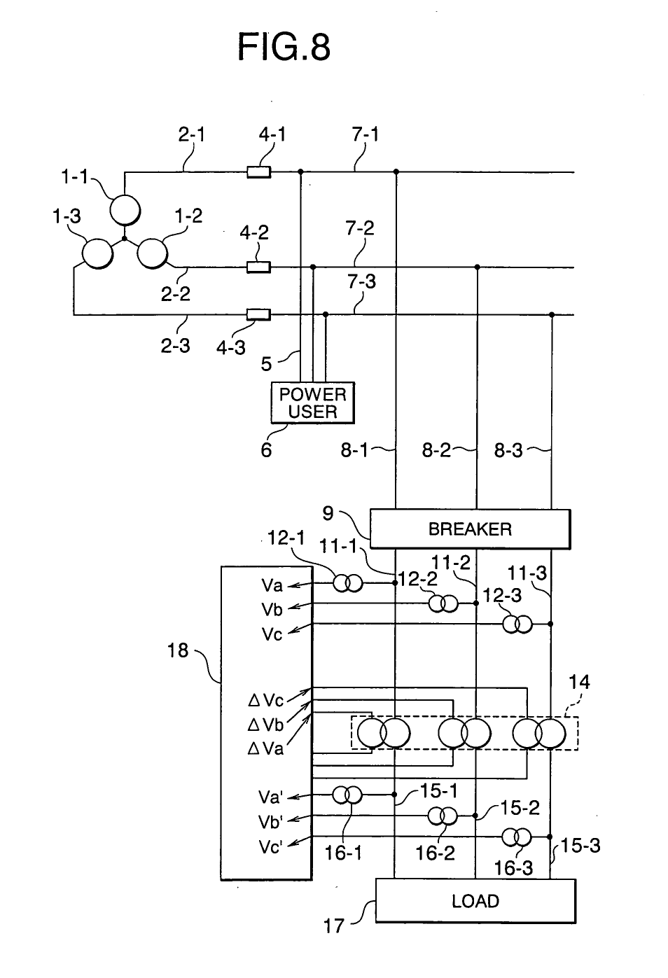

FIG. 8 is a circuit diagram, partly in block diagram, showing a configuration of a system for compensating a voltage of a negative-phase-sequence component according to Embodiment 2 of the present invention. Incidentally, in FIG. 8, the same constituent elements as those in FIG. 1 are designated with the same reference numerals, and the description thereof is omitted here for the sake of simplicity.

In FIG. 8, reference numerals 16-1, 16-2 and 16-3 respectively designate transformers (PTs) which are respectively connected to the connection lines 15-1, 15-2 and 15-3 distributed between the input unit 14 for compensation of a voltage of a negative-phase-sequence component and the load 17 in order to detect three-phase voltages after completion of the compensation. In this embodiment, voltages on the secondary sides of these transformers 16-1, 16-2 and 16-3 are taken out, and the detector 18 for detecting a voltage of a negative-phase-sequence component detects a voltage of a negative-phase-sequence component at this point to judge whether or not the voltage of a negative-phase-sequence component compensated for in Embodiment 1 shown in FIG. 1 is proper. That is to say, the feedback is carried out to perform the optimal compensation.

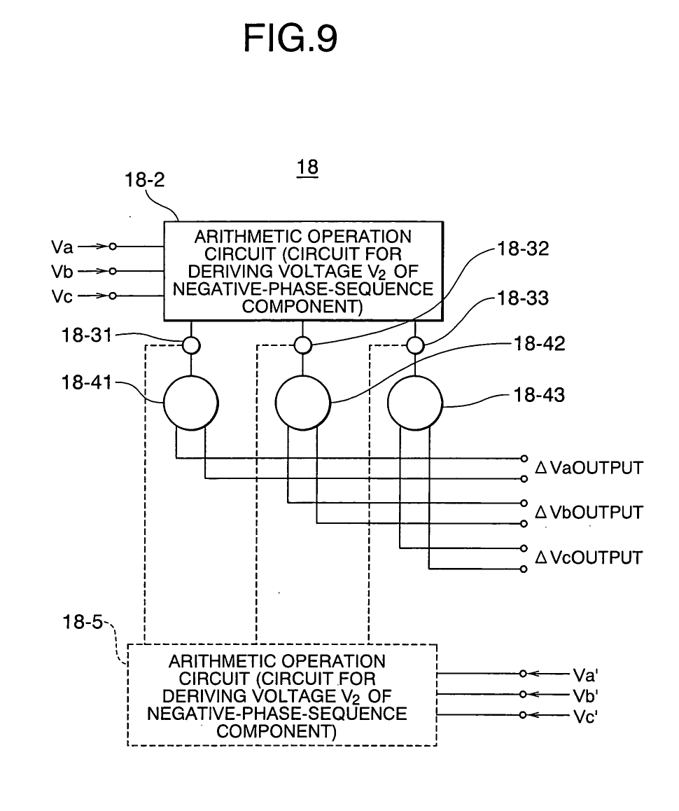

FIG. 9 is a circuit diagram, partly in block diagram, specifically showing a configuration of the detector 18 for detecting a voltage of a negative-phase-sequence component shown in FIG. 8. Incidentally, in FIG. 9, the same constituent elements as those shown in FIG. 2 are designated with the same reference numerals, and the description thereof is omitted here for the sake of simplicity. In FIG. 9, reference numeral 18-5 designates an arithmetic circuit for receiving as its inputs voltages Va′, Vb′ and Vc′ detected by the transformers 16-1, 16-2 and 16-3, respectively, to arithmetically operate the voltage V₂ of a negative-phase-sequence component therefrom. An arithmetic operation method in the arithmetic circuit 18-5 is the same as that in the above-mentioned arithmetic circuit 18-1. In such a manner, the voltage of a negative-phase-sequence component is derived from the voltages Va′, Vb′ and Vc′ after completion of the compensation detected by the transformers 16-l 16-2 and 16-3, respectively, to evaluate the suitability of the compensation. The derived voltage of a negative-phase-sequence component concerned is returned back to commanders (compensation quantity setting units) 18-31, 18-32 and 18-33 which carry out in turn addition/subtraction to adjust the compensation value. With such a method, the more proper compensation for the voltage of a negative-phase-sequence component becomes possible.

As described above, in this embodiment, the three-phase electric power system is provided with the arithmetic circuit 18-2 for deriving a voltage of a negative-phase-sequence component from the voltages received at the power receiving point, the detected voltage of a negative-phase-sequence component is amplified. Then the compensation is carried out for the voltages received at the power receiving point, and the voltage of a negative-phase-sequence component is cancelled for load equipment. Moreover, the degree of containing the voltage of a negative-phase-sequence component in the three-phase voltages after completion of the compensation is monitored. Hence, it becomes possible to supply balanced three-phase voltages to a load of a power user, and hence a three-phase rotating apparatus is prevented from falling into an over-load state to make the safety running thereof possible.

### Embodiment 3

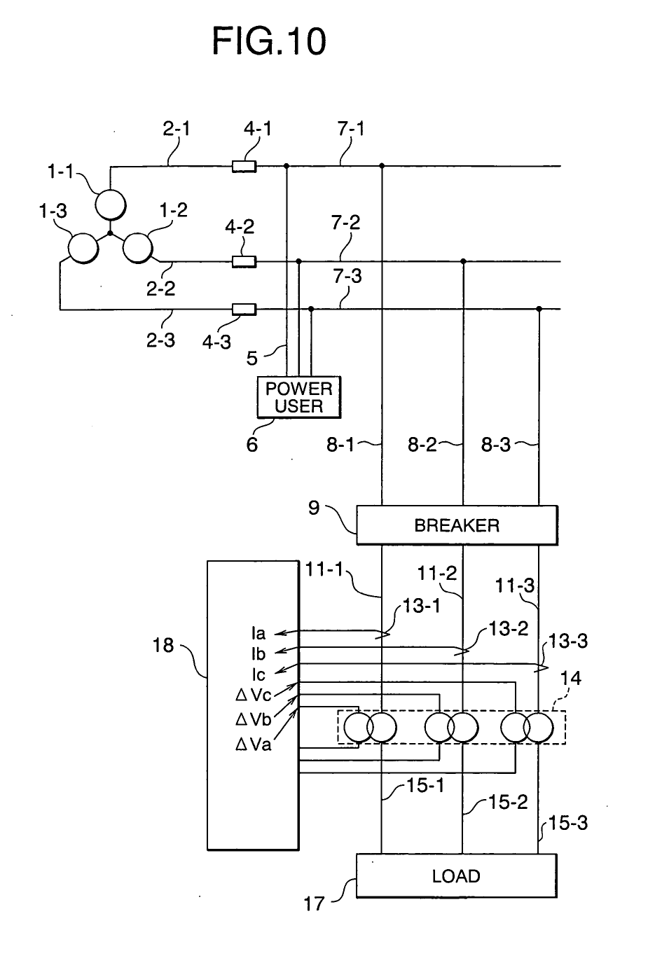

FIG. 10 is a circuit diagram, partly in block diagram, showing a configuration of a system for compensating a voltage of a negative-phase-sequence component according to Embodiment 3 of the present invention. Incidentally, in FIG. 10, the same constituent elements as those in FIGS. 1 and 8 are designated with the same reference numerals, and the description thereof is omitted here for the sake of simplicity.

In the above-mentioned embodiments, the description has been given with respect to an example in which the voltage of a negative-phase-sequence component is derived from the received voltages. In this embodiment, however, a current of a negative-phase-sequence component as an object of the compensation is derived from currents in the system. In FIG. 10, reference numerals 13-1, 13-2 and 13-3 respectively designate current transformers (CTs) which are connected to the connection lines 11-1, 11-2 and 11-3, respectively, in order to detect currents Ia, Ib and Ic received at the power receiving point. Then, the detected currents are induced into the detector 18 for detecting a voltage of a negative-phase-sequence component to derive a current of a negative-phase-sequence component from these currents in accordance with the above-mentioned method described with reference to FIGS. 7A, 7B and 7C to thereby carry out the compensation therefor.

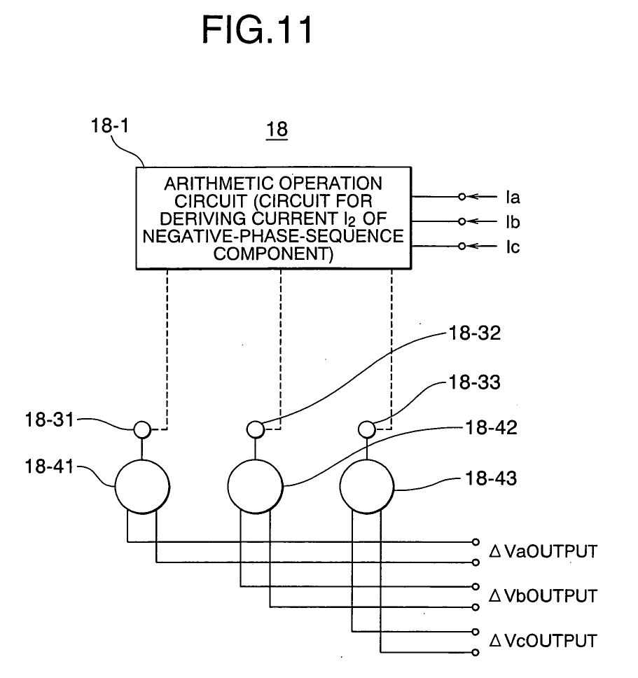

FIG. 11 is a circuit diagram, partly in block diagram, specifically showing a configuration of the detector 18 for detecting a voltage of a negative-phase-sequence component shown in FIG. 10. Incidentally, in FIG. 11, the same constituent elements as those shown in FIGS. 2 and 9 are designated with the same reference numerals, and the description thereof is omitted here for the sake of simplicity. In FIG. 11, reference numeral 18-1 designates an arithmetic circuit for arithmetically operating a current I₂ of a negative-phase-sequence component. In this embodiment, the current I₂ of a negative-phase-sequence component is detected from system currents Ia, Ib and Ic, and a voltage of a negative-phase-sequence component is derived with the method described with reference to FIGS. 7A, 7B and 7C to be induced into the commanders 18-31, 18-32 and 18-33 which command in turn a compensation quantity and a phase for the voltage of a negative-phase-sequence component, and then data of the compensation quantity is produced in the amplifiers 18-41, 18-42 and 18-43 to compensate the voltage of a negative-phase-sequence component. This method is suitable for a case where the compensation for a load can not be perfectly carried out only by a voltage because there is dispersion in three-phases on the load side.

As described above, in this embodiment, the three-phase electric power system is provided with the arithmetic circuit 18-1 for deriving a current of a negative-phase-sequence component from the currents received at the load point. Then the detected current of a negative-phase-sequence component is amplified to carry out the compensation for the currents at the load point to thereby cancel the current of a negative-phase-sequence component for load equipment. Hence, it becomes possible to supply the balanced three-phase voltages to a load of a power user, and hence a three-phase rotating apparatus is prevented from falling into an over-load state to make the safety running thereof possible.

### Embodiment 4

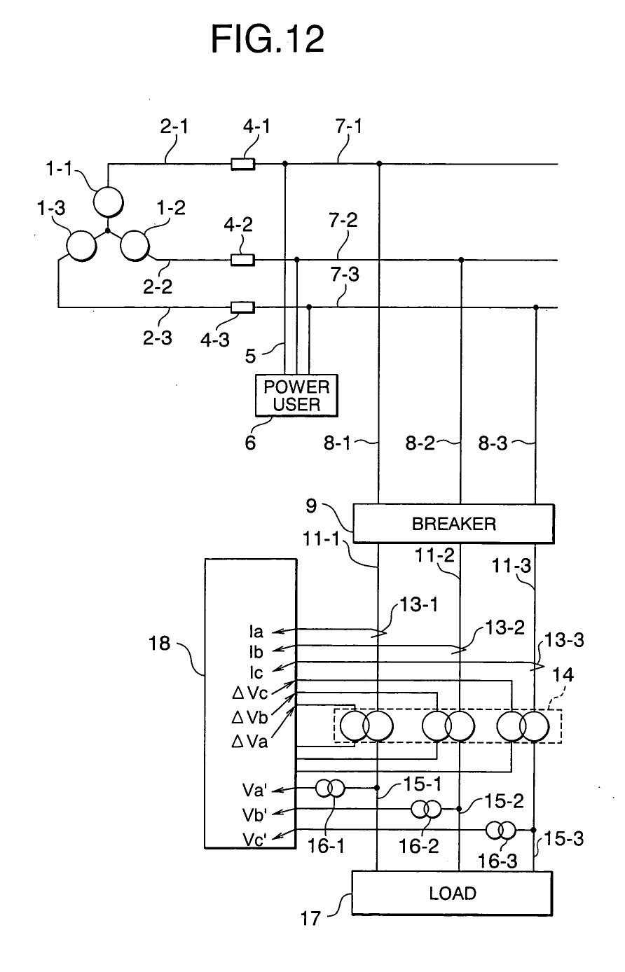

FIG. 12 is a circuit diagram, partly in block diagram, showing a configuration of a system for compensating a voltage of a negative-phase-sequence component according to Embodiment 4 of the present invention. Incidentally, in FIG. 12, the same constituent elements as those in FIG. 10 are designated with the same reference numerals, and the description thereof is omitted here for the sake of simplicity.

In FIG. 12, reference numerals 16-1, 16-2 and 16-3 respectively designate the transformers described and shown in the above-mentioned embodiment 2. These transformers serve to detect a voltage of a negative-phase-sequence component from the voltages after completion of the compensation to carry out feedback to the compensation setting circuit to thereby carry out the optimal compensation. A point of difference from the configuration of FIG. 10 in Embodiment 3 is that the transformers 16-1, 16-2 and 16-3 concerned are added.

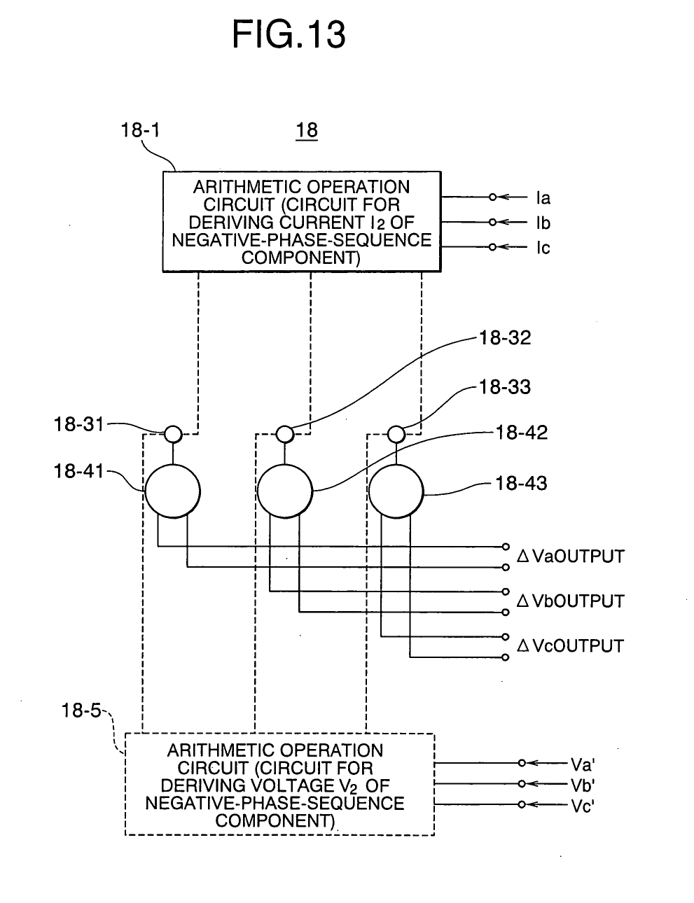

FIG. 13 is a circuit diagram, partly in block diagram, specifically showing a configuration of the detector 18 for detecting a voltage of a negative-phase-sequence component shown in FIG. 12. Incidentally, in FIG. 13, the same constituent elements as those shown in FIGS. 9 and 11 are designated with the same reference numerals, and the description thereof is omitted here for the sake of simplicity. The configuration of FIG. 13 is such that similarly to FIG. 9, the arithmetic circuit 18-5 as the deriving circuit for deriving the voltage V₂of a negative-phase-sequence component is further provided to the configuration of FIG. 11.

As described above, in this embodiment, the three-phase electric power system is provided with the arithmetic circuit 18-1 for deriving a voltage of a negative-phase-sequence component from the voltages received at the power receiving point, the detected voltage of a negative-phase-sequence component is amplified. Then the compensation is carried out for the voltages received at the power receiving point, and the voltage of a negative-phase-sequence component is cancelled for load equipment 17. Moreover, the degree of containing the voltage of a negative-phase-sequence component in the three-phase voltages after completion of the compensation is monitored. Hence, it becomes possible to supply balanced three-phase voltages to a load of a power user, and hence a three-phase rotating apparatus is prevented from falling into an over-load state to make the safety running thereof possible.

### Embodiment 5

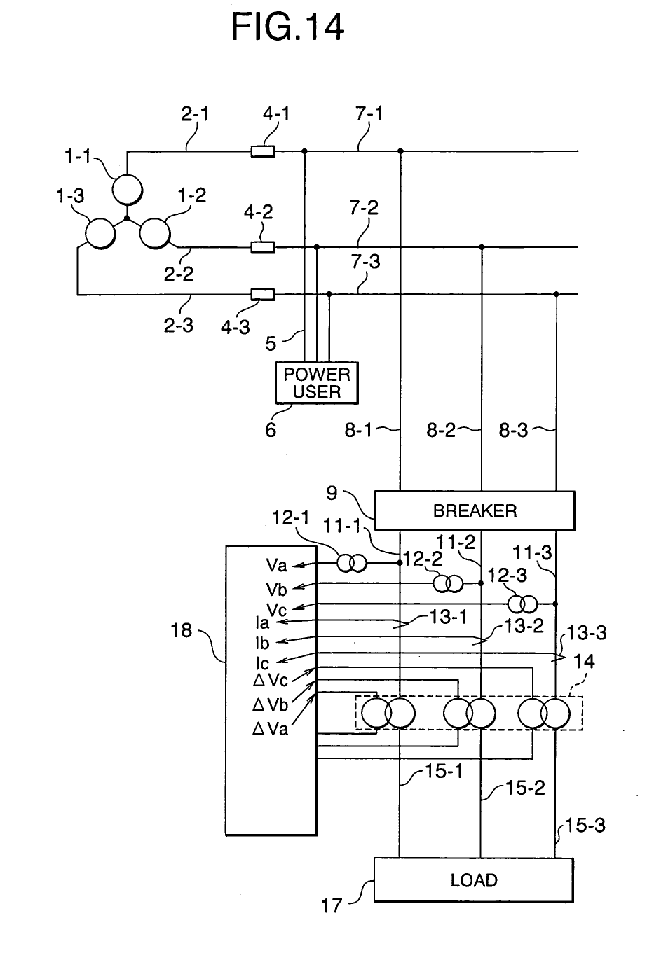

FIG. 14 is a circuit diagram, partly in block diagram, showing a configuration of a system for compensating a voltage of a negative-phase-sequence component according to Embodiment 5 of the present invention. Incidentally, in FIG. 14, the same constituent elements as those in FIGS. 1, 8, 10 and 12 are designated with the same reference numerals, and the description thereof is omitted here for the sake of simplicity.

FIG. 14 shows a configuration in case where a quantity of compensation for a negative-phase-sequence component is obtained from both line voltages and line currents. That is to say, this configuration is applied to a case where a sufficient quantity of compensation can not be obtained only from ones of the line voltages and the line currents. Incidentally, the configuration of FIG. 14 is such that the transformers 12-1, 12-2 and 12-3 shown in FIG. 1 are added to the configuration of FIG. 10.

This embodiment is effective for a case, for example, where while in a phase failure on the side of a rotating apparatus as an object requiring compensation therefor, unbalance of currents is large, voltages are drawn by the system voltages to keep a state near a state of a positive phase sequence.

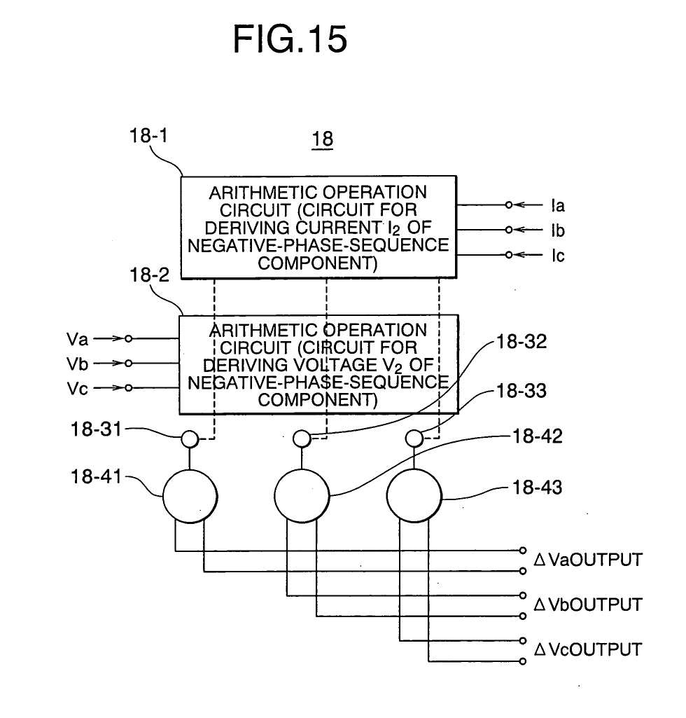

FIG. 15 shows an internal configuration of the detector 18 for detecting a voltage of a negative-phase-sequence component shown in FIG. 14. Incidentally, the same constituent elements as those of FIG. 2, FIG. 9, FIG. 11 and FIG. 13 are designated with the same reference-numerals, and the description thereof is omitted here for the sake of simplicity. In FIG. 15, reference numeral 18-2 designates an arithmetic operation circuit for deriving a voltage of a negative-phase-sequence component from voltages received at a load point, and reference numeral 18-1 designates the arithmetic circuit for deriving a voltage of a negative-phase-sequence component from currents received at a load point. That is to say, a voltage of a negative-phase-sequence component detected from the line voltages as well as a voltage of a negative-phase-sequence component detected from the line currents is added to the commanders 18-31, 18-32 and 18-33 to determine a quantity of compensation for a negative-phase-sequence component.

As described above, in this embodiment, the three-phase electric power system is provided with both the arithmetic circuit 18-2 for deriving a voltage of a negative-phase-sequence component from the voltages received at the load point and the arithmetic circuit 18-1 for deriving a voltage of a negative-phase-sequence component from the currents received at the load point, and the detected voltages of negative-phase-sequence components are amplified to carry out the compensation for the currents at the load point to thereby cancel the voltage of a negative-phase-sequence component for load equipment. Hence, it becomes possible to supply the balanced three-phase voltages to a load of a power user, and a three-phase rotating apparatus is prevented from falling into an over-load state to make the safety running thereof possible.

### Embodiment 6

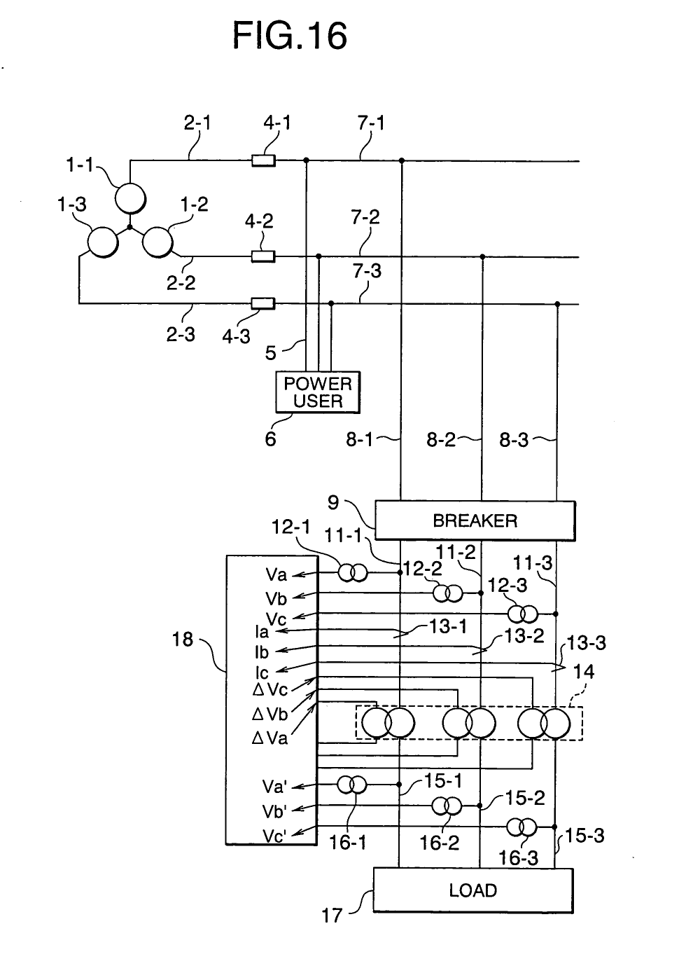

FIG. 16 is a circuit diagram, partly in block diagram, showing a configuration of a system for compensating a voltage of a negative-phase-sequence component according to Embodiment 6 of the present invention. Incidentally, in FIG. 16, the same constituent elements as those in FIGS. 1, 8, 10, 12 and 14 are designated with the same reference numerals, and the description thereof is omitted here for the sake of simplicity.

The configuration shown in FIG. 16 is such that the transformers 16-1, 16-2 and 16-3 shown in FIG. 12A are further added to the configuration shown in FIG. 14. That is to say, in the configuration of FIG. 16, in addition to the operation of FIG. 14, a state after completion of the compensation for a negative-phase-sequence component is monitored, excess and deficiency of the compensation for a negative-phase-sequence component is monitored, and feedback is carried out for the compensation quantity setting unit to carry out the optimal compensation.

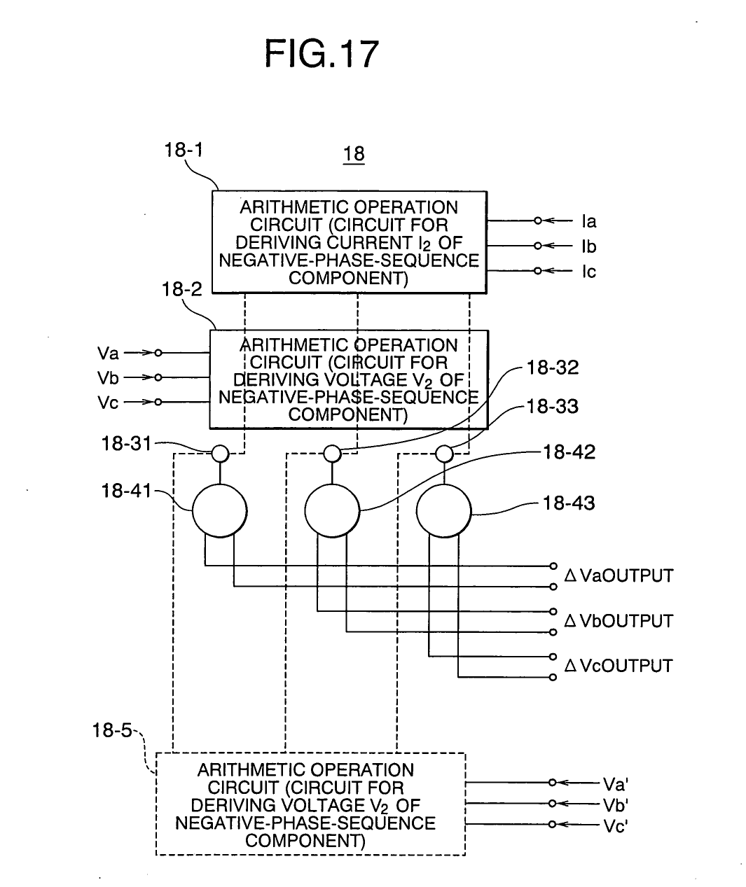

FIG. 17 shows a configuration of the detector 18 for detecting a voltage of a negative-phase-sequence component shown in FIG. 16. Incidentally, in FIG. 17, the same constituent elements as those of FIG. 2, FIG. 9, FIG. 11, FIG. 13 and FIG. 15 are designated with the same reference numerals, and the description thereof is omitted here for the sake of simplicity. In this embodiment, in order to determine a quantity of compensation, voltages and currents before the compensation and voltages after the compensation are monitored, and these voltages and currents are fed back to carry out the highly dense compensation for a voltage of a negative-phase-sequence component.

As described above, in this embodiment, the three-phase electric power system is provided with both the arithmetic circuit 18-2 for deriving a voltage of a negative-phase-sequence component from the voltages received at a load point, and the arithmetic circuit 18-1 for deriving a voltage of a negative-phase-sequence component from the currents received at a load point, the detected voltages of negative-phase-sequence components are amplified, the compensation is carried out for the voltages at the load point, and the voltage of a negative-phase-sequence component is cancelled for load equipment. Moreover, the degree of containing the voltage of a negative-phase-sequence component in the three-phase voltages after completion of the compensation is monitored. Consequently, it becomes possible to supply balanced three-phase voltages to a load of a power user, and hence a three-phase rotating apparatus is prevented from falling into an over-load state to make the safety running thereof possible.

What is claimed is:

1. A system for compensating a voltage of a negative-phase-sequence component in a power system, comprising:
received voltage detecting means for detecting received voltages at a power receiving point in a power system which is connected to load equipment;
negative-phase-sequence component voltage arithmetically operating means for arithmetically operating the voltage of a negative-phase-sequence component from the received voltages detected by the received voltage detecting means; and
negative-phase-sequence component voltage compensation inputting means for injecting a voltage based on the voltage of a negative-phase-sequence component into a system so as to compensate for the received voltages at the power receiving point,
wherein the voltage of a negative-phase-sequence components is cancelled to supply a power to the load equipment.

2. A system for compensating a voltage of a negative-phase-sequence component in a power system, comprising:
received current detecting means for detecting received currents at a power receiving point in a power system which is connected to load equipment;
negative-phase-sequence component voltage arithmetically operating means for arithmetically operating the voltage of a negative-phase-sequence component from the received currents detected by the received current detecting means; and
negative-phase-sequence component voltage compensation inputting means for injecting a voltage based on the voltages of a negative-phase-sequence component into a system so as to compensate for the received voltages at the power receiving point,
wherein the voltage of a negative-phase-sequence component is cancelled to supply a power to the load equipment.

3. A system for compensating a voltage of a negative-phase-sequence component in a power system, comprising:
received voltage detecting means for detecting received voltages at a power receiving point in a power system which is connected to load equipment;
received current detecting means for detecting received currents at the power receiving point in the electric power system;
negative-phase-sequence component voltage arithmetically operating means for arithmetically operating a first voltage of a negative-phase-sequence component from the received voltages detected by the received voltage detecting means, and for arithmetically operating a second voltage of a negative-phase-sequence component from the received currents detected by the received current detecting means; and
negative-phase-sequence component voltage compensation inputting means for injecting a voltage based on the first and second voltages of negative-phase-sequence components into a system so as to compensate for the received voltages at the power receiving point,
wherein the voltage of a negative-phase-sequence component is cancelled to supply a power to the load equipment.

4. A system for compensating a voltage of a negative-phase-sequence component in a power system according to claim 1, further comprising means for detecting received voltages after compensation which is provided between the negative-phase-sequence component voltage compensation inputting means and a load in order to detect a voltage of a negative-phase-sequence component after the compensation,
wherein a degree of containing the voltage of a negative-phase-sequence component in the voltages after the compensation is monitored.

5. A system for compensating a voltage of a negative-phase-sequence component in a power system according to claim 2, further comprising means for detecting received voltages after compensation which is provided between the negative-phase-sequence component voltage compensation inputting means and a load in order to detect a voltage of a negative-phase-sequence component after the compensation,
wherein a degree of containing the voltage of a negative-phase-sequence component in the voltages after the compensation is monitored.

6. A system for compensating a voltage of a negative-phase-sequence component in a power system according to claim 3, further comprising means for detecting received voltages after compensation which is provided between the negative-phase-sequence component voltage compensation inputting means and a load in order to detect a voltage of a negative-phase-sequence component after the compensation,
wherein a degree of containing the voltage of a negative-phase-sequence component in the voltages after the compensation is monitored.
